(19) United States
(12) Patent Application Publication
(10) Pub. No.: US 2024/0187758 A1
(43) Pub. Date: Jun. 6, 2024

(54) Zero Thermal Gradient Camera Core And Method For Making The Same

(71) Applicant: T-SMART PTE, LTD, Ubi Crescent (SG)

(72) Inventors: Bryan Patmon, Ubi Crescent (SG); Wei Kiong TAN, Ubi Crescent (SG)

(73) Assignee: T-SMART PTE, LTD, Ubi Crescent (SG)

(21) Appl. No.: 18/288,009

(22) PCT Filed: Apr. 22, 2021
(86) PCT No.: PCT/IB2021/000273

§ 371 Date: Oct. 23, 2023

(30) Foreign Application Priority Data
Apr. 22, 2021 (WO) PCT/IB2021/000273

(51) Int. Cl. H04N 25/78; H01L 27/146; H04N 23/51; H04N 25/131

(52) U.S. Cl. CPC H04N 25/78; H01L 27/1462; H01L 27/14632; H04N 23/51; H04N 25/131

(57) ABSTRACT

Camera device structures and methods of manufacturing them are disclosed. A sensor core includes a housing, a camera sensor, an integrated readout circuit, a controller (e.g., a processor unit for image processing), and a ceramic package base. In some examples, the sensor core includes a semiconductor-based micro machined cavity structure (e.g., based on an enclosure formed via the housing) with an integrated lens of the camera core package. The disclosure provides for a camera sensing core package with high reflection coating around walls of the housing, apart from the bottom ceramic base, which allows for maximum or rejection of stray radiation. The thermally balanced properties of the structure provide for improved thermal stability of the camera core of the device, while ensuring near zero thermal gradient across the camera sensor, which may result in improved performance of the camera sensing core.

### BACKGROUND

The following relates generally to camera devices, and more specifically to zero thermal gradient camera devices.

A device or an instrument may include one or more sensors (e.g., thermal imaging sensors, image sensors, cameras, etc.) for recording or capturing information, which may be stored locally or transmitted to another device. For example, an image sensor may capture visual information using one or more photosensitive elements that may be tuned for sensitivity to a visible spectrum of electromagnetic radiation. As another example, a thermal imaging sensor may capture thermal imaging information using one or more photosensitive elements (e.g., or thermo-optic elements) that may generally be tuned for sensitivity to some operating wavelength (e.g., such as an infrared (IR) spectrum or long-infrared (long-IR) spectrum of electromagnetic radiation, depending on the radiation being detected). The resolution of captured information may be measured in pixels, where each pixel may relate an independent piece of captured information. In some cases, each pixel may thus correspond to one component of, for example, a two-dimensional (2D) Fourier transform of an image or a heatmap. Computation methods may use the pixel information to reconstruct image information or thermal information captured by the sensor.

The disclosure is a solution to thermal gradient issues in camera devices. Among these, and without limitation, are more accurate remote temperature sensing.

### SUMMARY

The present disclosure describes example structures and methods of manufacturing a camera sensor core. In some embodiments, the sensor core includes a housing, a camera sensor (e.g., which can be tuned for sensitivity within a visible spectrum or an infrared (IR) spectrum)), an integrated readout circuit, a controller (e.g., an application specific integrated circuit (ASIC), a microcontroller (MCU), or processor unit for image processing), and a ceramic package base. In some examples, the sensor core includes a semiconductor-based micro machined cavity structure (e.g., based on an enclosure formed via the housing) with an integrated lens of the camera core package. Unlike traditional camera core packages, the disclosure provides for a package with high reflection coating around walls of the housing, apart from the bottom ceramic base, which allows for maximum or rejection of stray radiation. The thermally balanced properties of the structure provide for better overall thermal stability of the camera core of the device, while ensuring near zero thermal gradient across the camera sensor, which may result in improved performance of the overall camera core.

An apparatus (e.g., a camera device), system, and method for zero thermal gradient imaging are described. One or more embodiments of the apparatus, system, and method include a housing from a suitable material formed by bonding (fusion, eutectic or metallic) of multiple layers of wafer layers to a desired dimension. The housing may include walls defining an open sensor enclosure having a first and second end in spaced apart opposing relationship to each other, and the enclosure walls may further including a high reflection (HR) coating. In some embodiments, the housing enclosure affixed at a first end to a first surface of a ceramic base foundation. In some embodiments, the housing enclosure may have a lens affixed to and in sealing relation with the enclosure at a second end opposite the first surface of the ceramic base foundation. One or more embodiments of the apparatus, system, and method include an imaging sensor having at least one photo sensitive pixel sensitive to light in the visible to infrared wavelength range at a first surface, where the imaging sensor may be affixed at its second surface to first surface of a heat spreader. In some embodiments, the heat spreader may be affixed at a second surface opposite the heat spreader first surface to the first surface of the ceramic base foundation within the enclosure. One or more embodiments of the apparatus, system, and method include a standoff enclosure including walls defining the standoff enclosure, where the standoff enclosure may be affixed at a first end to the second surface of the imaging sensor. One or more embodiments of the apparatus, system, and method include a transparent window affixed to the standoff enclosure at a second end opposite to and in spaced apart relation to the first end, where the transparent window may be affixed to the second end in the presence of an inert gas. One or more embodiments of the apparatus, system, and method include a controller electrically connected to the sensor, where the controller may have memory and instructions for processing signals from the imaging sensor.

A method, apparatus, non-transitory computer readable medium, and system for zero thermal gradient camera devices are described. One or more embodiments of the method, apparatus, non-transitory computer readable medium, and system include forming an external housing from a wafer processing compatible material of suitable thermal conductivity in a repeated sequential process to form micro layers, forming a micro cavity in each micro layer of the external housing, and assembling the micro layers into a housing with an enclosure formed of the micro cavities. One or more embodiments of the method, apparatus, non-transitory computer readable medium, and system may further include applying an anti-reflective (AR) layer to the enclosure, affixing a lens to the enclosure at a first end of the enclosure, and affixing an imaging sensor sensitive to light in the range of visible light to infrared at a second surface to a first surface of a heat spreader. One or more embodiments of the method, apparatus, non-transitory computer readable medium, and system may further include affixing a standoff enclosure to the imaging sensor at its first surface, affixing a transparent window to the standoff in spaced apart relation to the sensor in the presence of an inert gas, affixing the heat spreader at a second surface to a first surface of a ceramic base foundation, and connecting a controller to the sensor electrically (e.g., the controller with memory and instructions to process signals from the sensor).

### BRIEF DESCRIPTION OF THE DRAWINGS

FIG. 1 shows an example of a zero thermal gradient camera device according to aspects of the present disclosure.

FIGS. 2 and 3 each show an example of a process for manufacturing a zero thermal gradient camera device according to aspects of the present disclosure.

### DETAILED DESCRIPTION

The present disclosure describes camera device structures (e.g., zero thermal gradient camera device structures) as well as methods of manufacturing such camera device structures. As an example, a camera device may include a housing (e.g., an enclosure), an imaging sensor, an integrated readout IC, a controller, and a base. An imaging sensor (e.g., a camera sensor chip) may include of a plurality of sensor pixels (e.g., sensor pixels tuned for sensitivity within a visible spectrum or an infrared (IR) spectrum). An integrated readout IC may be implemented for the readout of signals from the sensor pixels. The controller (e.g., an application specific integrated circuit (ASIC), a microcontroller (MCU), a processor unit, etc.) may perform one or more aspects of image processing of the readout signals and other auxiliary functions. In some examples, a base (e.g., a ceramic base) of the device may comprise suitable materials (e.g., such as beryllium oxide (BeO) or aluminum nitride (AlN)).

According to aspects described herein, the housing may include a micro machined enclosure that is formed based on a wafer level process (e.g., and is subsequently singulated). The enclosure seals elements of the camera device (e.g., the imaging sensor, integrated readout IC, controller, etc.) in addition to providing for a high thermal conductivity. In some embodiments, the enclosure may be anti-reflection (AR) coated to provide for a high transmission window for the wavelength region of interest. In some embodiments, the enclosure may be high-reflection (HR) coated to reflect emissions of undesired wavelengths.

As such, the techniques and structures described herein may increase emission transmission provided by an etched AR cap (e.g., lens) and may simplify wafer scale packaging for imaging sensors with a wafer level cap. Further, due to the overall construct, the techniques and structures described herein may improve thermal stability provided by a thermally efficient conductive enclosure, and thus may result in near zero thermal gradient at an imaging sensor (e.g., at a sensor chip).

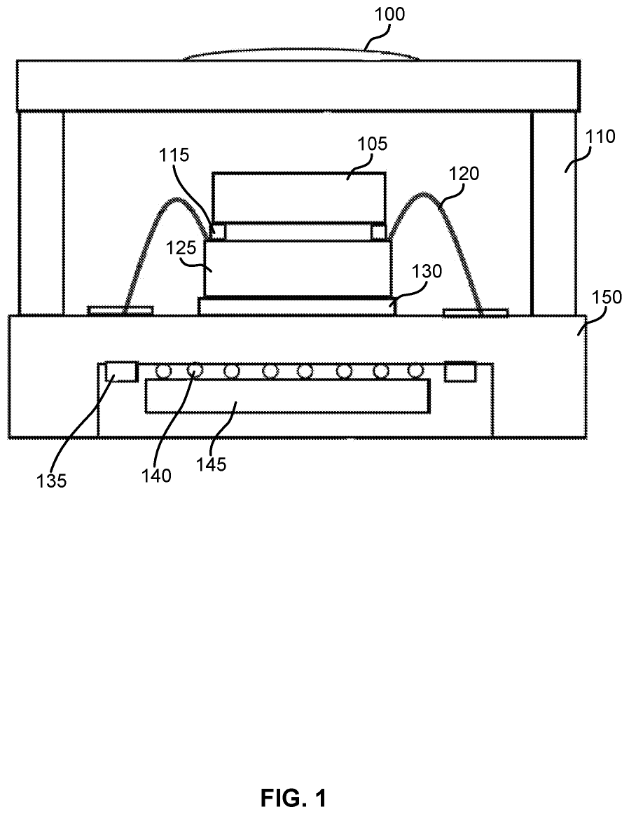

FIG. 1 shows an example of a zero thermal gradient camera device according to aspects of the present disclosure. The example shown includes lens 100, transparent window 105, housing 110, imaging sensor standoff 115, wire bonding 120, imaging sensor 125, heat spreader 130, passives 135, gold bumping 140, controller 145, and ceramic substrate 150.

FIG. 1 illustrates aspects of an example camera device according to one or more aspects of the present disclosure. The camera device may include an imaging sensor 125. The imaging sensor 125 may include a plurality of photo sensitive pixels, integrated with a CMOS readout IC, sealed with a transparent window 105 (e.g., a transparent window 105 filter) with a standoff enclosure (e.g., a cavity) formed between the imaging sensor 125 and transparent window 105 (e.g., via the imaging sensor standoff 115). In some embodiments, the standoff enclosure (e.g., the cavity) may be filled with a dry inert gas. The material of the transparent window 105 may include Silicon, Germanium, glass or any other suitable material dependent on the intended wavelength window of operation. The process of sealing the transparent window 105 to the imaging sensor standoff 115 is carried out at wafer level (e.g., based on a wafer level process) before singulation. The imaging sensor 125 is then eutectic bonded to a heat spreader 130 material with suitable thermal properties. This bonded structure is then eutectic bonded to the ceramic substrate 150 (e.g., base), which functions as both the base of the overall package and the electrical connection paths of the I/O pins.

That is, the imaging sensor 125 (e.g., including the sealed transparent window 105, the standoff enclosure, etc.) bonded to a heat spreader 130 may be referred to as a bonded imaging sensor 125 structure. In some cases, the heat spreader 130 may be referred to as a heat transfer substrate. In some examples, before the bonding of the base (e.g., a ceramic substrate 150) to the bonded imaging sensor 125 structure, a controller 145 (e.g., an ASIC, a MCU, a processor unit, etc.), which is gold bumped or include gold bumping 140, is first flip chip mounted to backside of the ceramic substrate 150 base. Passives 135 (e.g., such as capacitors and resistors) may be implemented for efficient operation of the controller 145. In some examples, passives 135 may be mounted to the ceramic substrate 150 base. Wire bonding 120 may then be carried out to form connections between the imaging sensor 125 and an I/O interface of the ceramic substrate 150 base.

A controller 145 (e.g., or processor) may generally include an intelligent hardware device, (e.g., a general-purpose processing component, a digital signal processor (DSP), a central processing unit (CPU), a graphics processing unit (GPU), a microcontroller, an ASIC, a field programmable gate array (FPGA), a programmable logic device, a discrete gate or transistor logic component, a discrete hardware component, or any combination thereof). In some cases, the controller 145 is configured to operate a memory array using a memory controller. In other cases, a memory controller is integrated into the controller 145. In some cases, the controller 145 is configured to execute computer-readable instructions stored in a memory to perform various functions. In some embodiments, a controller 145 includes special purpose components for modem processing, baseband processing, digital signal processing, or transmission processing.

An I/O interface (e.g., an I/O interface of the ceramic substrate 150 base) may provide data and information to control circuitry (e.g., of the ceramic substrate 150 base), which includes processing circuitry and storage. Control circuitry may be used to send and receive commands, requests, and other suitable data using I/O connectors of the I/O interface. I/O connectors may connect control circuitry (and specifically processing circuitry) to one or more communications paths. I/O functions may be provided by one or more of these communications paths. Control circuitry may be based on any suitable processing circuitry such as processing circuitry. Processing circuitry may include circuitry based on one or more microprocessors, microcontrollers, digital signal processors, programmable logic devices, FPGAs, ASICs, etc., and may include a multi-core processor (e.g., dual-core, quadcore, hexa-core, or any suitable number of cores) or supercomputer. In some embodiments, processing circuitry may be distributed across multiple separate processors or processing units, for example, multiple of the same type, or different type, of processing units.

The housing 110 may provide an enclosure, comprising of a cavity structure, that may be micro machined from suitable semiconductor material (e.g., Si, may be first formed by fusion bonding multiple layers of choice semiconductor wafers to achieve the desired enclosure clearance height). Alternatively, this cavity structure may be micro machined from a thick glass wafer. In both structures, the lens 100 (e.g., the final semiconductor lens 100 layer) may be first subjected to a patterning and etch process to achieve the desired AR effect and lens 100 structure. The cavity structure of the enclosure may be formed by either micro machining of the semiconductor wafer stack or the glass wafer to form the cavity of designed dimension. In some examples, the micro machining process is tuned to ensure an anisotropic profile to maintain a reduced footprint (e.g., a minimum footprint achievable) while allowing for the intended field of view cone. The lens 100 (e.g., the semiconductor lens 100 layer) may then be bonded to the cavity enclosure (e.g., to a top surface of the housing 110). Dependent on intended application, AR coating layers (e.g., for maximum transmission) or HR coating layers (e.g., for rejection of IR to prevent system heat up due to IR absorption) may be further deposited on the desired areas to improve the overall performance of the packaged camera device. The housing 110 (e.g., the enclosure and the bonded imaging sensor 125 structure, etc.) is finally bonded to the ceramic base, for example, in a dry inert gas filled environment.

Methods of imaging sensor 125 packaging is described. For example, a method may include packaging an imaging sensor 125 with a total minimal thermal gradient consisting of a silicon thermopile sensor mounted directly to a silicon substrate using a carbon-filled adhesive and subsequently mounted to a second substrate composed of aluminum nitride or beryllium oxide. In some examples, the imaging sensor 125 is eutectic bonded to a suitable heat spreader 130 acting as a sink.

Methods may include forming a hermetic seal (e.g., the housing 110 enclosure having a lens 100 affixed to and in sealing relation) to create a completed package unit, where a silicon cavity enclosure may be made up of multiple silicon layers, may additionally be integrated with a silicon lens 100, and may be bonded around (e.g., completely around) the periphery of an alumina nitride-composed substrate of geometric shape.

Some methods may include forming a hermetic seal (e.g., the housing 110 enclosure having a lens 100 affixed to and in sealing relation) to create a completed package unit, where a glass cavity enclosure may be made up of a single glass layer, may additionally be integrated with a silicon lens 100, and may be bonded around (e.g., completely around) the periphery of an alumina nitride-composed substrate of geometric shape.

In accordance with the techniques described herein, a camera device (e.g., a zero thermal gradient camera device) is described. One or more embodiments of the camera device include a housing 110 from a suitable material formed by bonding (fusion, eutectic or metallic) of multiple layers of wafer layers to a desired dimension. The housing 110 includes walls defining an open sensor enclosure having a first and second end in spaced apart opposing relationship to each other. The enclosure walls further include a HR coating, and the housing 110 enclosure may be affixed at a first end to a first surface of a ceramic base foundation. The housing 110 enclosure may have a lens 100 affixed to, and in sealing relation with, the enclosure at a second end opposite the first surface of the ceramic base foundation. One or more embodiments of the camera device include an imaging sensor 125 that may have at least one photo sensitive pixel sensitive to light in the visible to infrared wavelength range at a first surface. The imaging sensor 125 may be affixed at its second surface to first surface of a heat spreader 130. The heat spreader 130 may be affixed at a second surface opposite the heat spreader 130 first surface to the first surface of the ceramic base foundation within the enclosure. One or more embodiments of the camera device include a standoff enclosure that may include walls defining the standoff enclosure, where the standoff enclosure is affixed at a first end to the second surface of the imaging sensor 125. One or more embodiments of the camera device include a transparent window 105 that may be affixed to the standoff enclosure at a second end opposite to and in spaced apart relation to the first end. The transparent window 105 may be affixed to the second end in the presence of an inert gas. One or more embodiments of the camera device include a controller 145 that may be electrically connected to the sensor, and the controller 145 may have memory and instructions for processing signals from the imaging sensor 125.

A system for zero thermal gradient imaging sensing is described, the system comprising a housing 110 from a suitable material formed by bonding (fusion, eutectic or metallic) of multiple layers of wafer layers to a desired dimension. The housing 110 may include walls defining an open sensor enclosure having a first and second end in spaced apart opposing relationship to each other. The enclosure walls may further include a HR coating, and the housing 110 enclosure may be affixed at a first end to a first surface of a ceramic base foundation. The housing 110 enclosure may have a lens 100 affixed to and in sealing relation with the enclosure at a second end opposite the first surface of the ceramic base foundation. The system may further comprise an imaging sensor 125 having at least one photo sensitive pixel sensitive to light in the visible to infrared wavelength range at a first surface. The imaging sensor 125 may be affixed at its second surface to first surface of a heat spreader 130, where the heat spreader 130 may be affixed at a second surface opposite the heat spreader 130 first surface to the first surface of the ceramic base foundation within the enclosure. The system may further comprise a standoff enclosure including walls defining the standoff enclosure. The standoff enclosure may be affixed at a first end to the second surface of the imaging sensor 125. The system may further comprise a transparent window 105 affixed to the standoff enclosure at a second end opposite to and in spaced apart relation to the first end. The transparent window 105 may be affixed to the second end in the presence of an inert gas. The system may further comprise a controller 145 electrically connected to the sensor, where the controller 145 may have memory and instructions for processing signals from the imaging sensor 125.

A method of manufacturing a camera device (e.g., a zero thermal gradient camera device) is described. The method includes providing a housing 110 from a suitable material formed by bonding (fusion, eutectic or metallic) of multiple layers of wafer layers to a desired dimension. The housing 110 may include walls defining an open sensor enclosure having a first and second end in spaced apart opposing relationship to each other, and the enclosure walls may further include a HR coating. The housing 110 enclosure may be affixed at a first end to a first surface of a ceramic base foundation. The housing 110 enclosure may have a lens 100 affixed to, and in sealing relation with, the enclosure at a second end opposite the first surface of the ceramic base foundation. The method may further include providing an imaging sensor 125 having at least one photo sensitive pixel sensitive to light in the visible to infrared wavelength range at a first surface, where the imaging sensor 125 may be affixed at its second surface to first surface of a heat spreader 130. The heat spreader 130 may be affixed at a second surface opposite the heat spreader 130 first surface to the first surface of the ceramic base foundation within the enclosure. The method may further include providing a standoff enclosure including walls defining the standoff enclosure, where the standoff enclosure may be affixed at a first end to the second surface of the imaging sensor 125. The method may further include providing a transparent window 105 affixed to the standoff enclosure at a second end opposite to and in spaced apart relation to the first end, where the transparent window 105 may be affixed to the second end in the presence of an inert gas. The method may further include providing a controller 145 electrically connected to the sensor, where the controller 145 may have memory and instructions for processing signals from the imaging sensor 125.

In some examples, the housing 110 is comprised of silicon, germanium or glass and mixtures thereof. In some examples, the housing 110 is formed by bonding of multiple layers of semiconductor wafers. In some examples, the enclosure is formed by micro-machining the housing 110 to an anisotropic profile. In some examples, the lens 100 layer has anti-reflective property. In some examples, the controller 145 is a read out integrated circuit for readout of signals from the light sensitive sensor. In some examples, the controller 145 is an application specific integrated circuit, micro controller 145 or microprocessor unit for image or data processing of readout signals from the thermal imaging sensor 125. In some examples, the controller 145 is a gold bumped (e.g., the controller 145 includes gold bumping 140), first flip chip mounted to a second surface of the ceramic base foundation opposite the first surface of the ceramic base foundation. Some examples of the device, system, and method described above further include a passives 135 such as resistors and capacitors mounted on the second surface of the ceramic base foundation and electrically connected to the controller 145. In some examples, the ceramic base foundation is made of beryllium oxide, alumina nitride, and mixtures thereof. In some examples, the lens 100 is made of glass, silicon, germanium and mixtures thereof. In some examples, the transparent window 105 is made of glass, silicon, germanium and mixtures thereof.

A method of manufacturing an image sensor camera (e.g., a zero thermal gradient camera device) is described. One or more embodiments of the method include forming an external housing 110 from a wafer processing compatible material of suitable thermal conductivity in a repeated sequential process to form micro layers, forming a micro cavity in each micro layer of the external housing 110, assembling the micro layers into a housing 110 with an enclosure formed of the micro cavities, and applying an anti-reflective layer to the enclosure. The method may further include affixing a lens 100 to the enclosure at a first end of the enclosure and affixing an imaging sensor 125 sensitive to light in the range of visible light to infrared at a second surface to a first surface of a heat transfer substrate (e.g., a heat spreader 130). The method may further include affixing a standoff enclosure to the imaging sensor 125 at its first surface and affixing a transparent window 105 to the standoff in spaced apart relation to the sensor in the presence of an inert gas, affixing the heat transfer substrate (e.g., the heat spreader 130) at a second surface to a first surface of a ceramic base foundation, and connecting a controller 145 to the sensor electrically (e.g., the controller 145 with memory and instructions to process signals from the sensor).

In some examples, the enclosure is formed by micro machining wafers followed by bonding multiple layers of wafers to achieve a desired enclosure dimension. In some examples, the lens 100 is coated to provide antireflective properties. In some examples, the lens 100 is made of glass, silicon, geranium, and mixtures thereof. In some examples, the transparent window 105 is made from glass, germanium, silicon, and mixtures thereof. In some examples, the controller 145 is a read out integrated circuit for readout of signals from the thermal sensitive sensor. In some examples, the controller 145 is an application specific integrated circuit, micro controller 145 or microprocessor unit for image or data processing of readout signals from the imaging sensor 125. In some examples, the controller 145 is a gold bumped (e.g., the controller 145 includes gold bumping 140), first flip chip mounted to a second surface of the ceramic base foundation opposite the first surface of the ceramic base foundation.

According to some embodiments, a camera device described herein (e.g., the packaging structure) may include micro-machined enclosures (e.g., housing enclosure, standoff enclosure) that are formed by the removal of small amounts of material for a specific design (e.g., as applicable for implementing sensing elements), and that are subsequently bonded (e.g., by a optically protective layer). In some examples, such may be manufactured through Wafer-level optics (WLO) enabling miniaturized optics to be incorporated at the wafer level and subsequently singulated.

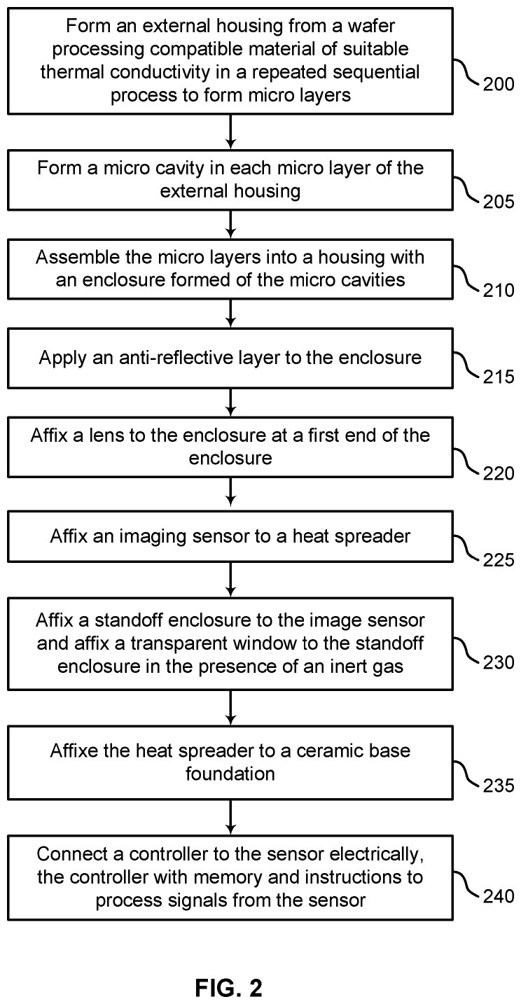

FIG. 2 shows an example of a process for manufacturing a zero thermal gradient camera device according to aspects of the present disclosure. In some examples, these operations are performed by a manufacturing system including a processor executing a set of codes to control functional elements of the manufacturing system (e.g., such as manufacturing robotics). Additionally or alternatively, certain processes are performed using special-purpose hardware, human interaction, etc. Generally, these operations are performed according to the methods and processes described in accordance with aspects of the present disclosure. In some cases, the operations described herein are composed of various sub-steps, or are performed in conjunction with other operations.

At operation 200, the system forms an external housing from a wafer processing compatible material of suitable thermal conductivity in a repeated sequential process to form micro layers. In some cases, the operations of this step refer to a housing as described with reference to FIG. 1.

At operation 205, the system forms a micro cavity in each micro layer of the external housing. In some cases, the operations of this step refer to a housing as described with reference to FIG. 1.

At operation 210, the system assembles the micro layers into a housing with an enclosure formed of the micro cavities. In some cases, the operations of this step refer to a housing as described with reference to FIG. 1.

At operation 215, the system applies an anti-reflective layer to the enclosure. In some cases, the operations of this step refer to a housing as described with reference to FIG. 1.

At operation 220, the system affixes a lens to the enclosure at a first end of the enclosure. In some cases, the operations of this step refer to a lens and a housing as described with reference to FIG. 1.

At operation 225, the system affixes an imaging sensor sensitive to light in the range of visible light to infrared at a second surface to a first surface of a heat transfer substrate (e.g., a heat spreader). In some cases, the operations of this step refer to an imaging sensor and a heat spreader as described with reference to FIG. 1.

At operation 230, the system affixes a standoff enclosure to the image sensor at its first surface and affixing a transparent window to the standoff in spaced apart relation to the sensor in the presence of an inert gas. In some cases, the operations of this step refer to an imaging sensor, an imaging sensor standoff, and a transparent window as described with reference to FIG. 1.

At operation 235, the system affixes the heat transfer substrate at a second surface to a first surface of a ceramic base foundation. In some cases, the operations of this step refer to a heat spreader and a ceramic substrate as described with reference to FIG. 1.

At operation 240, the system connects a controller to the sensor electrically, the controller with memory and instructions to process signals from the sensor. In some cases, the operations of this step refer to a controller as described with reference to FIG. 1.

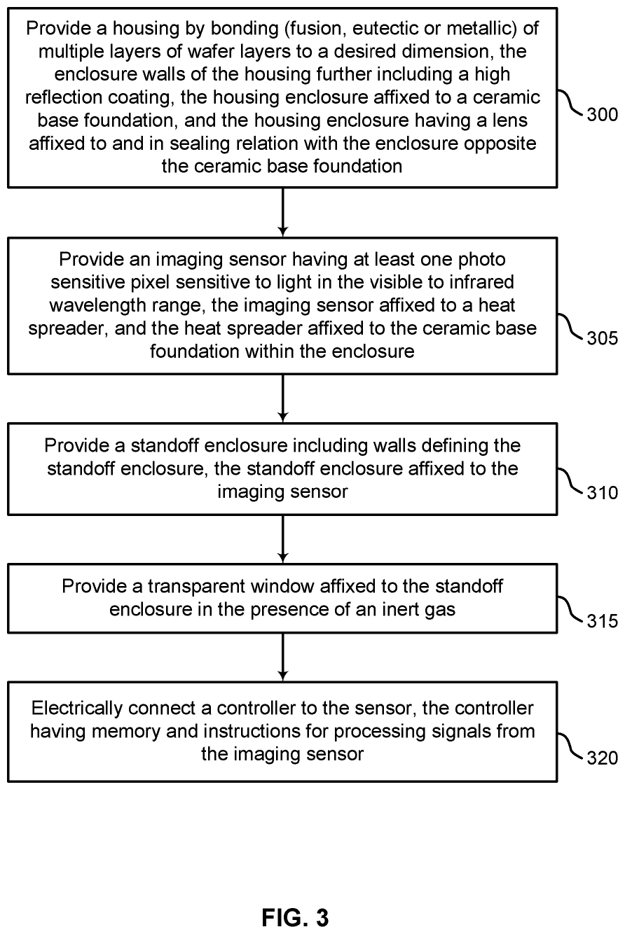

FIG. 3 shows an example of a process for manufacturing a zero thermal gradient camera device according to aspects of the present disclosure. In some examples, these operations are performed by a manufacturing system including a processor executing a set of codes to control functional elements of the manufacturing system (e.g., such as manufacturing robotics). Additionally or alternatively, certain processes are performed using special-purpose hardware, human interaction, etc. Generally, these operations are performed according to the methods and processes described in accordance with aspects of the present disclosure. In some cases, the operations described herein are composed of various substeps, or are performed in conjunction with other operations.

At operation 300, the system provides a housing from a suitable material formed by bonding (fusion, eutectic or metallic) of multiple layers of wafer layers to a desired dimension; the housing including walls defining an open sensor enclosure having a first and second end in spaced apart opposing relationship to each other; the enclosure walls further including a high reflection coating; the housing enclosure affixed at a first end to a first surface of a ceramic base foundation; the housing enclosure having a lens affixed to and in sealing relation with the enclosure at a second end opposite the first surface of the ceramic base foundation. In some cases, the operations of this step refer to a housing as described with reference to FIG. 1.

At operation 305, the system provides an imaging sensor having at least one photo sensitive pixel sensitive to light in the visible to infrared wavelength range at a first surface; the imaging sensor affixed at its second surface to first surface of a heat spreader; the heat spreader affixed at a second surface opposite the heat spreader first surface to the first surface of the ceramic base foundation within the enclosure. In some cases, the operations of this step refer to an imaging sensor as described with reference to FIG. 1.

At operation 310, the system provides a standoff enclosure including walls defining the standoff enclosure, the standoff enclosure affixed at a first end to the second surface of the imaging sensor. In some cases, the operations of this step refer to an imaging sensor standoff as described with reference to FIG. 1.

At operation 315, the system provides a transparent window affixed to the standoff enclosure at a second end opposite to and in spaced apart relation to the first end; the transparent window affixed to the second end in the presence of an inert gas. In some cases, the operations of this step refer to a transparent window as described with reference to FIG. 1.

At operation 320, the system provides a controller electrically connected to the sensor; the controller having memory and instructions for processing signals from the imaging sensor. In some cases, the operations of this step refer to a controller as described with reference to FIG. 1.

The description and drawings described herein represent example configurations and do not represent all the implementations within the scope of the claims. For example, the operations and steps may be rearranged, combined or otherwise modified. Also, structures and devices may be represented in the form of block diagrams to represent the relationship between components and avoid obscuring the described concepts. Similar components or features may have the same name but may have different reference numbers corresponding to different figures.

Some modifications to the disclosure may be readily apparent to those skilled in the art, and the principles defined herein may be applied to other variations without departing from the scope of the disclosure. Thus, the disclosure is not limited to the examples and designs described herein, but is to be accorded the broadest scope consistent with the principles and novel features disclosed herein.

The described systems and methods may be implemented or performed by devices that include a general-purpose processor, a DSP, an ASIC, a FPGA or other programmable logic device, discrete gate or transistor logic, discrete hardware components, or any combination thereof. A general-purpose processor may be a microprocessor, a conventional processor, controller, microcontroller, or state machine. A processor may also be implemented as a combination of computing devices (e.g., a combination of a DSP and a microprocessor, multiple microprocessors, one or more microprocessors in conjunction with a DSP core, or any other such configuration). Thus, the functions described herein may be implemented in hardware or software and may be executed by a processor, firmware, or any combination thereof. If implemented in software executed by a processor, the functions may be stored in the form of instructions or code on a computer-readable medium.

Computer-readable media includes both non-transitory computer storage media and communication media including any medium that facilitates transfer of code or data. A non-transitory storage medium may be any available medium that can be accessed by a computer. For example, non-transitory computer-readable media can comprise random access memory (RAM), read-only memory (ROM), electrically erasable programmable read-only memory (EEPROM), compact disk (CD) or other optical disk storage, magnetic disk storage, or any other non-transitory medium for carrying or storing data or code.

Also, connecting components may be properly termed computer-readable media. For example, if code or data is transmitted from a website, server, or other remote source using a coaxial cable, fiber optic cable, twisted pair, digital subscriber line (DSL), or wireless technology such as infrared, radio, or microwave signals, then the coaxial cable, fiber optic cable, twisted pair, DSL, or wireless technology are included in the definition of medium. Combinations of media are also included within the scope of computer-readable media.

In this disclosure and the following claims, the word “or” indicates an inclusive list such that, for example, the list of X, Y, or Z means X or Y or Z or XY or XZ or YZ or XYZ. Also the phrase “based on” is not used to represent a closed set of conditions. For example, a step that is described as “based on condition A” may be based on both condition A and condition B. In other words, the phrase “based on” shall be construed to mean “based at least in part on.” Also, the words “a” or “an” indicate “at least one.”

1. A zero thermal gradient camera device, comprising;
a housing from a suitable material formed by bonding of multiple layers of wafer layers to a desired dimension; the housing including walls defining an open sensor enclosure having a first and second end in spaced apart opposing relationship to each other; the enclosure walls further including a high reflection coating; the housing enclosure affixed at a first end to a first surface of a ceramic base foundation; the housing enclosure having a lens affixed to and in sealing relation with the enclosure at a second end opposite the first surface of the ceramic base foundation;
an imaging sensor having at least one photo sensitive pixel sensitive to light in the visible to infrared wavelength range at a first surface; the imaging sensor affixed at its second surface to first surface of a heat spreader; the heat spreader affixed at a second surface opposite the heat spreader first surface to the first surface of the ceramic base foundation within the enclosure;
a standoff enclosure including walls defining an enclosure, the window enclosure affixed at a first end to the second surface of the imaging sensor;
a transparent widow affixed to the window enclosure at a second end opposite to and in spaced apart relation to the first end; the transparent window affixed to the second end in the presence of an inert gas; and
a controller electrically connected to the sensor; the controller having memory and instructions for processing signals from the imaging sensor.

2. The zero thermal gradient camera of claim 1, wherein the housing is comprised of at least one of silicon, germanium or glass.

3. The zero thermal gradient camera of claim 1, wherein the housing is formed by bonding of multiple layers of semiconductor wafers.

4. The zero thermal gradient camera of claim 1, wherein the enclosure is formed by micro-machining the housing to an anisotropic profile.

5. The zero thermal gradient camera of claim 1, wherein the lens layer has an antireflective property.

6. The zero thermal gradient camera of claim 1, wherein the controller is a read out integrated circuit for readout of signals from the light sensitive sensor.

7. The zero thermal gradient camera of claim 1, wherein the controller is an application specific integrated circuit, micro controller or microprocessor unit for image or data processing of readout signals from the thermal imaging sensor.

8. The zero thermal gradient camera of claim 1, wherein the controller is a gold bumped, first flip chip mounted to a second surface of the ceramic base foundation opposite the first surf ace of the ceramic base foundation.

9. The zero thermal gradient camera of claim 1, further including passives such as resistors and capacitors mounted on the second surface of the ceramic base foundation and electrically connected to the controller.

10. The zero thermal gradient camera of claim 1, wherein the ceramic base foundation is made of at least one of beryllium oxide or alumina nitride.

11. The zero thermal gradient camera of claim 1, wherein the lens is made of at least one of glass, silicon, or germanium.

12. The zero thermal gradient camera of claim 1, wherein the transparent vacuum cap is made of at least one of glass, silicon, or germanium.

13. A method of manufacturing an image sensor camera, comprising;
forming an external housing from a wafer processing compatible material of suitable thermal conductivity in a repeated sequential process to form micro layers;
forming a micro cavity in each micro layer of the external housing;
assembling the micro layers into a housing with an enclosure formed of the micro cavities;
applying an anti-reflective layer to the enclosure;
affixing a lens to the enclosure at a first end of the enclosure;
affixing an image sensor sensitive to light in the range of visible light to infrared at a second surface to a first surface of a heat transfer substrate;
affixing a standoff enclosure to the image sensor at its first surface and affixing a transparent window to the standoff in spaced apart relation to the sensor in the presence of an inert gas;
affixing the heat transfer at a second surf ace to a first surf ace of a ceramic base foundation; and
electrically connecting a controller to the sensor, the controller with memory and instructions to process signals from the sensor.

14. The method of claim 13, wherein the enclosure is formed by micro machining wafers followed by bonding multiple layers of wafers.

15. The method of claim 13, wherein the lens is coated to provide antireflective properties.

16. The method of claim 13, wherein the lens is made of at least one of glass, silicon, or geranium.

17. The method of claim 13, wherein the transparent window is made from at least one of glass, germanium, or silicon.

18. The method of claim 13, wherein the controller is a read out integrated circuit for readout of signals from the thermal sensitive sensor.

19. The method of claim 13, wherein the controller is an application specific integrated circuit, micro controller or microprocessor unit for image or data processing of readout signals from the imaging sensor.

20. The method of claim 13, wherein the controller is a gold bumped, first flip chip mounted to a second surface of the ceramic base foundation opposite the first surface of the ceramic base foundation.
